(19) United States
(12) Patent Application Publication
(10) Pub. No.: US 2026/0231343 A1
(43) Pub. Date: Aug. 6, 2026

(54) ASSEMBLY WITH MICROMOBILITY DEVICE CONNECTIVITY

(71) Applicant: Also, Inc., Palo Alto, CA (US)

(72) Inventor: Trevor James EDMONDS, Redwood City, CA (US)

(73) Assignee: Also, Inc., Palo Alto, CA (US)

(21) Appl. No.: 19/529,565

(22) Filed: Feb. 4, 2026

Related U.S. Application Data
(60) Provisional application No. 63/754,094, filed on Feb. 5, 2025.

(51) Int. Cl. H05K 5/00; B60L 50/20; B60R 16/023

(52) U.S. Cl. CPC H05K 5/0073; B60L 50/20; B60R 16/0239; H05K 5/0069; B60L 2200/12; B60L 2240/622; B60L 2270/40

(57) ABSTRACT

An assembly, for an electric bicycle, can include a housing. The housing can receive a first connectivity assembly and a second connectivity assembly. The housing can be disposed at least partially within a frame of the electric bicycle. The first connectivity assembly can house a first antenna. The second connectivity assembly can house a second antenna. The assembly can include at least one processor coupled with memory. The at least one processor can receive, from at least one of the first antenna or the second antenna, an input. The at least one processor can cause the electric bicycle to perform an action based on the input.

### CROSS-REFERENCE TO RELATED PATENT APPLICATIONS

This application claims the benefit of and priority to U.S. Provisional Patent Application No. 63/754,094, filed February 5, 2025, the entirety of which is incorporated by reference herein for all purposes.

### INTRODUCTION

Bicycles can include energy storage devices.

### SUMMARY

This disclosure is generally related to one or more components of a bicycle. The components can include at least one assembly. The assembly can include one or more additional assemblies or sub-assemblies. For example, the assembly can include one or more connectivity assemblies. The connectivity assemblies can facilitate communication between the bicycle and one or more devices. For example, the connectivity assemblies can include communication devices (e.g., antennas, receivers, transmitters, receivers, etc.) to transmit or receive information. The connectivity assemblies can communicate with one or more computing devices (e.g., processors coupled with memory, microcontroller units, systems-on-chip, etc.). For example, the connectivity assemblies can include a near-field communication (NFC) antenna that can transmit data (via short-range communication) to a microcontroller unit (MCU). The MCU can, based on the data from the NFC antenna, cause performance one or more actions. The actions can be performed by the bicycle or one or more components thereof. For example, the actions can include a light source of the bicycle producing light. As another example, the actions can include adjusting an amount of energy discharged by one or more energy storage devices of the bicycle. As another example, the actions can include actuation (e.g., activation, deactivation, enable, disable, etc.) of a drive unit such that bike switches from an operating mode to a disabled mode, or vice versa.

At least one aspect is directed to an assembly. The assembly can be for an electric bicycle. The assembly can include a housing. The housing can receive a first connectivity assembly and a second connectivity assembly. The housing can be disposed at least partially within a frame of the electric bicycle. The first connectivity assembly can include a first printed circuit board (PCB). The first PCB can house a first communication device associated with a first communication protocol. The second connectivity assembly can include a second PCB. The second PCB can house a second communication device associated with a second communication protocol. The assembly can include a processor coupled with memory. The processor can receive, from at least one of the first communication device or the second communication device, one or more inputs. The processor can cause the electric bicycle to perform at least one action based on the one or more inputs.

At least one aspect is directed to a method. The method can include providing a housing of an assembly. The assembly can be for an electric bicycle. The housing can receive a first connectivity assembly and a second connectivity assembly. The housing can be disposed at least partially within a frame of the electric bicycle. The first connectivity assembly can include a first printed circuit board (PCB). The first PCB can house a first communication device associated with a first communication protocol. The second connectivity assembly can include a second PCB. The second PCB can house a second communication device associated with a second communication protocol. The assembly can include a processor coupled with memory. The processor can receive, from at least one of the first communication device or the second communication device, one or more inputs. The processor can cause the electric bicycle to perform at least one action based on the one or more inputs.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts an example bicycle, in accordance with some aspects.

FIG. 2 depicts a perspective view of the bicycle of FIG. 1, in accordance with some aspects.

FIG. 3 depicts an assembly for the bicycle of FIG. 1, in accordance with some aspects.

FIG. 4 depicts a perspective view of a frame of the bicycle of FIG. 1, in accordance with some aspects.

FIG. 5 depicts a perspective view of a frame of the bicycle of FIG. 1, in accordance with some aspects.

FIG. 6 depicts a perspective view of a frame of the bicycle of FIG. 1, in accordance with some aspects.

FIG. 7 depicts a connectivity assembly included in the assembly of FIG. 3, in accordance with some aspects.

FIG. 8 depicts a sub-assembly for a connectivity assembly included in the assembly of FIG. 3, in accordance with some aspects.

FIG. 9 depicts a sub-assembly for a connectivity assembly included in the assembly of FIG. 3, in accordance with some aspects.

FIG. 10 depicts the assembly of FIG. 3, in accordance with some aspects.

FIG. 11 depicts the assembly of FIG. 3, in accordance with some aspects.

FIG. 12 is a block diagram illustrating an architecture for a computing system that can be employed to implement elements of the systems and methods described and illustrated herein.

FIG. 13 is a block diagram of a process to provide an assembly, in accordance with some aspects.

FIG. 14 is a block diagram of a process to control an electric bike, in accordance with some aspects.

### DETAILED DESCRIPTION

Following below are more detailed descriptions of various concepts related to, and implementations of, methods, apparatuses, and systems of one or more assemblies for a bicycle. The various concepts introduced above and discussed in greater detail below may be implemented in one or more numerous ways.

The present disclosure is directed to one or more components for a micromobility device such as a bicycle. The components can include one or more assemblies for the bicycle, such as connectivity assemblies. The connectivity assemblies can include communication devices (e.g., antennas, transmitters, receivers, transceivers, etc.) to relay information between components. For example, the connectivity assemblies can detect a presence of a computing device (e.g., a mobile phone, a smart watch, a tag, a fob, etc.) within a proximity of the bicycle. The connectivity assemblies can (responsive to detection of the presence) cause the bicycle or one or more components thereof to perform one or more actions. The actions can include an activation (or unlock) of a drive train or other primary mover of the bicycle. Stated otherwise, the drive train can be inoperable or deactivated prior to detection of the presence of the computing device. As another example, the actions can include activation or execution of a light illumination pattern. Stated otherwise, the connectivity assemblies can cause one or more light sources to produce light responsive to detection of the presence of the computing device.

The connectivity assemblies can be disposed or otherwise placed within one or more portions or components of the bicycle. For example, the connectivity assemblies can be disposed within a down tube (e.g., a frame) of the bicycle. The down tube can include a hollow portion (e.g., a cavity, a void, a chamber, space, opening, etc.) to receive or otherwise accept a housing. The housing can include or otherwise house the connectivity assemblies. The connectivity assemblies can refer to or include sub-assemblies, modules, or sub-components. For example, the connectivity assemblies can be sub-assemblies that form or otherwise define an assembly or an apparatus.

Bicycle assemblies that house or otherwise include communication devices, can be limited with respect to offerings (e.g., services, features, etc.) and functionality. These limitations result from the assemblies conforming to a single protocol, such as communication protocols. Devices that are restricted to a single protocol can only provide offerings that conform to the single protocol. As a result of the restrictions, bicycles are unable to provide offerings associated with additional protocols.

The disclosed solutions have a technical advantage of providing an assembly that includes connectivity assemblies with communication devices associated with one or more protocols, such as wireless communication protocols. For example, the assembly can include a Bluetooth device and an ultra-wide band (UWB) device. Advantageously, the assembly can provide offerings associated with Bluetooth (e.g., a first wireless communication protocol) or offerings associated with UWB (e.g., a second wireless communication protocol).

Systems and methods of the present technical solution also include arranging or placing the assembly within a down tube (e.g., a frame) of the bicycle such that the assembly is secured or otherwise positioned within a typically unoccupied area of a bicycle. For example, placement of the assembly within the down tube can be accomplished without repositioning or relocating devices of the bicycle. Additionally, placement of the assembly within the frame of the bicycle improves accessibility of one or more communication devices of the assembly. For example, an NFC antenna can be positioned on a top or upper side of the frame such that a mobile device or NFC tag can seamlessly interface (e.g., interact) with the NFC antenna to trigger one or more actions by the bicycle. The actions can include locking or unlocking a drive unit (e.g., actuation of the drive unit), a production of light, an audible greeting, among other possible actions.

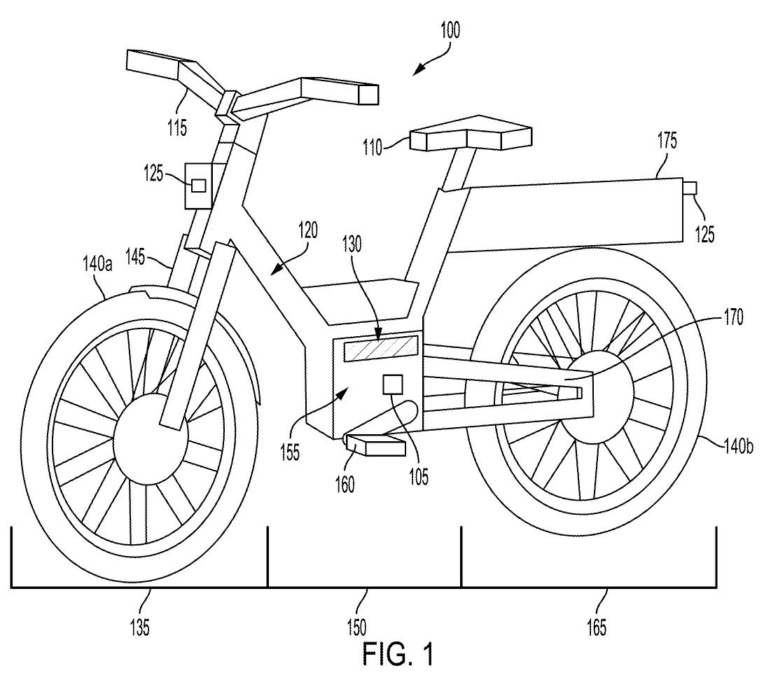

FIG. 1 depicts an example perspective view of a micromobility device such as a bicycle (referred to generally herein as bike 100). The bike 100 can be an electric bike installed with at least one battery pack 105. The bike 100 can include at least one bicycle. The bike 100 can be a human-operated bike. The bike 100 can include single rider bicycles, tandem bicycles, cargo bicycles, motor-assist bicycles, pedicabs, electric-assist bicycles, road bicycles, mountain bicycles, or unicycles, one wheel, two wheel, three wheel, and four or more than four wheel bikes or vehicles, among others. The battery pack 105 can also be used as an energy storage system to power a building, such as a residential home or commercial building. The bike 100 can be fully electric or partially electric (e.g., pedal-powered) and further, the bike 100 can be fully autonomous, partially autonomous, semi-autonomous, or unmanned. The bike 100 can also be human operated or non-autonomous. A human operator or the rider of the bike 100 can sit on a saddle 110 to operate the bike 100. The rider of the bike 100 can steer, grip, balance, or otherwise control the bike 100 using the handlebar 115.

The battery pack 105 can refer to or include at least one of an assembly, a sub-assembly, a standalone device, or other possible components or apparatuses. While the battery pack 105, in some examples, has been described as a separate or discreate element of the bike 100, the battery pack 105 can be included in an assembly which further include one or more additional sub-assemblies. Stated otherwise, the battery pack 105 can be housed or otherwise located within a housing that further houses additional elements/assemblies of the bike 100.

The bike 100 can include a frame 120. The frame 120 can support various components of the bike 100, such as a handlebar 115, the saddle 110, the battery pack 105, at least one light 125, and at least one lock assembly 130. The frame 120 can refer to or include a down tube. The frame 120 can span a front portion 135. The front portion 135 can support, be coupled with, or include, for example, a wheel of the bike 100, a fork 145 of the bike 100, the handlebar 115, the light 125, among other components. The bike 100 can include two or more wheels (e.g., shown as front wheel 140a and rear wheel 140b). The frame 120 can span a middle portion 150. The middle portion 150 can support, be coupled with, or include, for example, the saddle 110, the battery pack 105, a crank shaft or drive mechanism (shown as drive unit 155 of the bike 100), or a pedal 160 of the bike 100, among other components. The frame 120 can include the middle portion 150 including the lock assembly 130. The frame 120 can include a rear portion 165. The rear portion 165 can support, be coupled with, or include, for example, the rear wheel 140b, the light 125, a drive train 170 of the bike 100, or a rack 175 of the bike 100, among other components. The battery pack 105 can be disposed anywhere within the frame 120.

The battery pack 105 can include at least one battery, at least one battery module, or at least one battery cell. The battery pack 105 can be electrically coupled with the bike 100 (e.g., to the drive unit 155, to the light 125, the lock assembly 130, or some other components). For example, the battery pack 105 can provide electrical energy to the bike 100 to power the bike 100. The battery pack 105 can be installed or placed within the bike 100. For example, the battery pack 105 can be installed on the frame 120 of the bike 100 within one or more of the front portion 135, the middle portion 150, or the rear portion 165. The battery pack 105 can be integrally coupled with the frame 120 such that it is not removable. The battery pack 105 can be detachably coupled with the frame 120 such that in can be removed (e.g., to charge the battery pack 105). The battery pack 105 can include or connect with at least one busbar, e.g., a current collector element. For example, the busbar can include electrically conductive material to connect or otherwise electrically couple the battery pack 105 with other electrical components of the bike 100 to provide electrical power to various systems or components of the bike 100, such as the lock assembly 130 or some other system.

As shown in FIG. 1, the lock assembly 130 can be coupled with the frame 120. For example, the lock assembly 130 can be at least partially integrated with the frame 120 of the bike 100 such that at least a portion of the lock assembly 130 can be inseparable from, built within, permanently coupled with, or otherwise integrated with the frame 120 of the bike 100. The battery pack 105 can be coupled with the frame 120 via one or more receivers. The lock assembly 130 can be positioned within the middle portion 150 of the bike 100 and beneath the saddle 110 or proximate the drive unit 155 and pedal 160.

The bike 100 can include the lock assembly 130 electrically coupled with the battery pack 105. For example, the battery pack 105 can be electrically coupled with a receiver of the lock assembly 130 to facilitate the actuation or movement of one or more components of the receiver. In this way, the receiver can be configured to be controlled or actuated electronically via power provided by the battery pack 105, rather than being controlled or actuated manually or mechanically (e.g., via some manual action of an operator). For example, the battery pack 105 can provide power to the drive unit 155 to power the bike 100 (e.g., propel the bike 100 by causing at least one of the front wheel 140a or the rear wheel 140b to rotate) and also provide power to the receiver to operate the lock assembly 130. The battery pack 105 can provide power to the lock assembly 130 and other components of the bike 100 (e.g., the drive unit 155, the light 125, or some other component) simultaneously, separately, in sequence, or in some other manner.

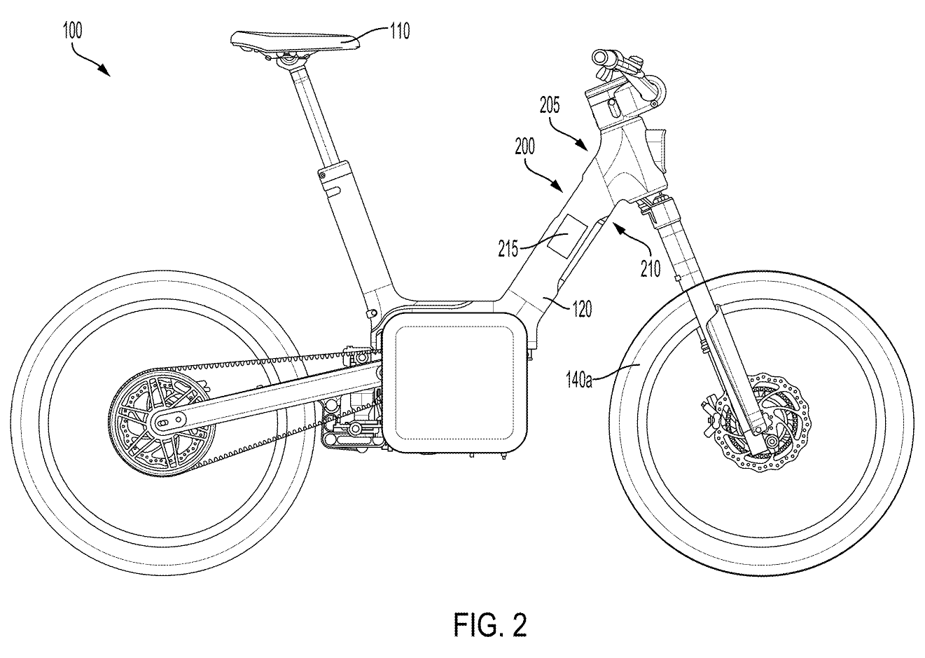

FIG. 2 depicts a perspective view of the bike 100, in accordance with some aspects. The bike 100 can include at least one assembly 200. For example, as shown in FIG. 2, the assembly 200 is included at least partially within the frame 120. The assembly 200 can refer to or include at least one of the assemblies, the sub-assemblies, the modules, the components, or the sub-components described herein. For example, the assembly 200 can include the connectivity assemblies described herein.

The frame 120 can include at least one portion. The portions of the frame 120 can refer to or include one or more of sides, segments, parts, sections, or areas. For example, as shown in FIG. 2, the frame 120 includes a first side 205 (e.g., a top side) and a second side 210 (e.g., a bottom side). The first side 205 and the second side 210 can be disposed opposite to one another. Stated otherwise, the first side 205 and the second side 210 can be opposite sides of the frame 120. The assembly 200 or one or more components thereof can be positioned, disposed, placed, or otherwise located proximate to at least one portion (e.g., the first side 205, the second side 210, etc.) of the frame 120. For example, a connectivity assembly (of the assembly 200) can be proximate to the first side 205 such that the connectivity assembly resides on or is otherwise within a threshold distance of the first side 205.

The assembly 200 can be disposed within one or more field of views of the bike 100. For example, a component (e.g., a sub-assembly, a communication assembly, or a housing, etc.) of the assembly 200 can be disposed (on the bike 100) such that the component is within view (e.g., visible) from a particular portion, segment, or component of the bike 100. As another example, the communication assembly (of the assembly 200) can be disposed on the frame 120 such that the communication assembly is within a field of view or otherwise visible from the saddle 110. Stated otherwise, the communication assembly is visible while an operator of the bike 100 is on the saddle 110 or otherwise looking at the frame 120 from the perspective of the saddle 110.

The assembly 200 can include at least one controller 215. The controller 215 can include at least one processor coupled with memory. The controller 215 can refer to or include at least one of a microcontroller unit, a system-on-chip, a computing device, a processing circuit, processing units (e.g., central processing units, graphic processing units, execution units, etc.), or electrical circuitry.

The memory of the controller 215 can include one or more memory devices or hardware devices to store information. For example, the memory can include Read Only Memory (ROM) or Random Access Memory (RAM). The memory can include primary memory and secondary memory. For example, the memory can include one or more solid state drives (SSDs) or memory modules (e.g., RAM sticks, memory chips, etc.). The memory can store at least one of instructions, executable code, firmware, or software. The information (e.g., instructions, etc.) stored in the memory can, when executed, cause the controller 215 to implement at least one of the various processes, systems, functionality, or capabilities described herein. For example, the controller 215 can execute instructions to control or otherwise cause the connectivity assemblies to perform one or more functions or actions based on one or more inputs or triggers. The actions can include activation or deactivation of one or more components of the bike 100. For example, the controller 215 can actuate the drive unit 155 to lock (e.g., disable the pedal 160 or pedal assembly) or unlock (e.g., allow for rotation of the pedal 160). As another example, the controller 215 can activate one or more lights (e.g., the light 125) to cause a production of light.

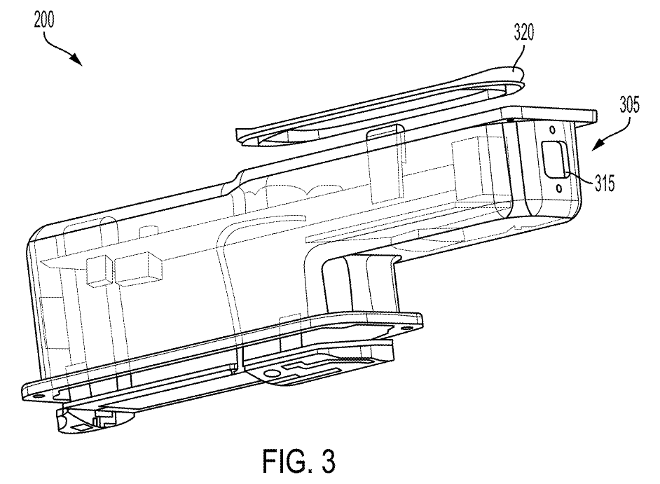

FIG. 3 depicts the assembly 200, in accordance with some aspects. The assembly 200 can include at least one housing 305. The housing 305 can refer to or include at least one of a body, structural support, an enclosure, or a case. The housing 305 can include one or more form factors, dimensions, shapes, arrangements, or appearances. The assembly 200 can include at least one member 320. The member 320 can be removably coupled with at least one portion of the housing 305. For example, the member 320 can be coupled with the housing 305 via one or more fasteners. As another example, the member 320 can be decoupled from the housing 305 responsive to removal of the fasteners. The member 320 can provide one or more of a barrier, a shield, a wall, or a blockade for the housing 305. The member 320 can refer to or include an interlocking member.

The housing 305 can include at least one aperture 315. The aperture 315 can provide at least one of an opening, a void, a gap, or a hole for which components can enter or exit the housing. For example, as shown in FIG. 3, the aperture 315 can provide an opening for components (e.g., cabling, wiring, connectors, etc.) to exit the housing 305.

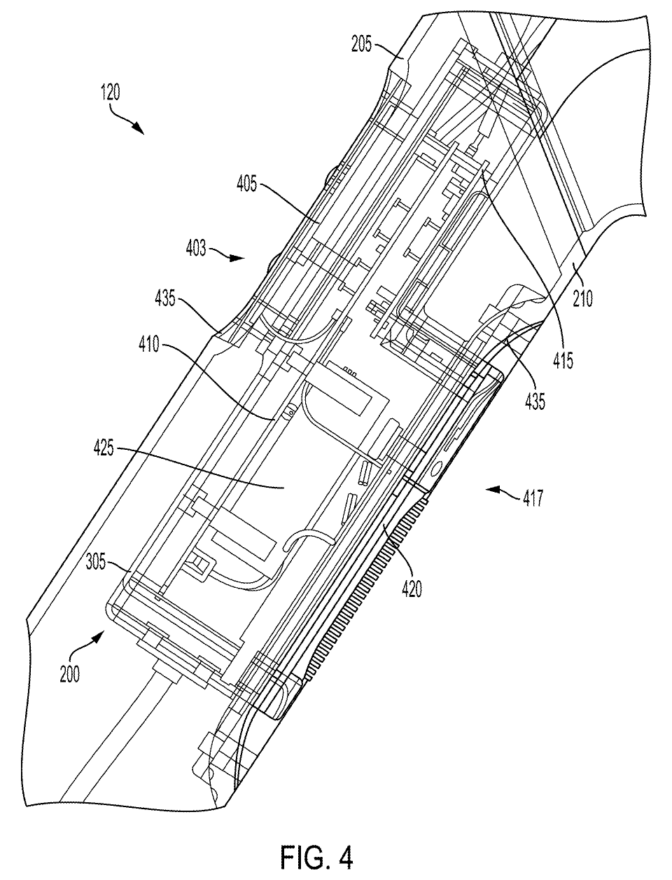

FIGS. 4-6 depict perspective views of the frame 120, in accordance with some aspects. The perspective view of the frame 120, as shown in FIG. 4, can refer to or include a cross-sectional view or a transparent view such that one or more components disposed within the frame 120 are visible. The assembly 200 can include at least one assembly or sub-assembly. For example, as shown in FIG. 4, the assembly 200 includes a connectivity assembly 403 and a connectivity assembly 417. At least one of the connectivity assembly 403 or the connectivity assembly 417 can refer to a first connectivity assembly or a second connectivity assembly. The connectivity assemblies (e.g., the connectivity assembly 403, the connectivity assembly 417, etc.) can be disposed proximate to at least one portion or side of the frame 120. For example, as shown in FIG. 4, the connectivity assembly 403 is disposed proximate to the side 205. As another example, as shown in FIG. 4, the connectivity assembly 417 is disposed proximate to the side 210.

The housing 305 can include one or more apertures to receive or otherwise couple with members of the assembly 200. For example, as shown in FIG. 4, the housing 305 includes apertures 435. The apertures 435 can provide an area or an opening for one or more components of the assembly 200. For example, a first aperture 435 (shown disposed on the side 205) can provide an area for at least a portion of the connectivity assembly 403. As another example, a second aperture 435 (shown disposed on the side 210) can provide an area for at least a portion of the connectivity assembly 417. The member 320 can couple with or be secured to the housing 305 via the apertures 435.

The connectivity assemblies can include one or more components such as, ground planes, printed circuit boards, communication devices, traces, connectors, or terminals. For example, as shown in FIG. 4, the connectivity assembly 403 includes a PCB 405 and a PCB 410. As another example, as shown in FIG. 4, the connectivity assembly 417 includes a PCB 420. As another example, the assembly 200 can include a PCB 415 to facilitate control of one or more energy storage devices (e.g., batteries, power sources, etc.). At least one of the PCB 405, the PCB 410, the PCB 415, or the PCB 420 can refer to or include a first PCB, a second PCB, a third, PCB, and so on. In FIG. 4, the assembly 200 is shown as including one or more battery packs 425. The battery packs 425 can include or refer to the battery pack 105. The battery packs 425 can provide energy to one or more components of the bike 100.

The respective PCBs (of the assembly 200) can include or otherwise support one or more communication devices. For example, a first PCB (e.g., the PCB 405) of the assembly 200 can include an NFC antenna (e.g., a first communication device) which operates at approximately 13.56 MHZ and within a magnetic near-field region. As another example, a second PCB (e.g., the PCB 420) of the assembly 200 can include an LTE antenna (e.g., a second communication device) which operates at one or more cellular bands, such as between 600 MHz and 900 MHz, 17000 MHz and 2200 MHz, or 2500 MHz and 2700 MHz. Given that the NFC antenna and the LTE antenna operate at substantially different electromagnetic regimes, direct radio-frequency cross-talk does not typically occur. Regardless, the spacing and structural arrangement (of the PCB 405 and the PCB 420) within the housing 305 can be selected to mitigate the possibility of cross-talk concerns (e.g., NFC detuning, magnetic loading, parasitic capacitive coupling, broadband electrical noise, etc.).

As an example, and as shown in FIG. 4, the PCB 405 and the PCB 420 can be spaced apart or otherwise separated from one another (withing the housing 305). The spacing or distance between the PCB 405 and the PCB 420 can be selected to address potential signal interference (e.g., cross-talk, signal attenuation, etc.) between communication devices located on the PCB 405 or the PCB 420. For example, the PCB 405 and the PCB 420 can be positioned (within the housing 305) to establish a separation distance to reduce potential magnetic-field interaction between the NFC antenna (on PCB 405) and one or more conductive structures of the PCB 420. The conductive structures of the PCB 420 can include one or more of ground planes, radio frequency feed traces, shielding cans, metallic fasteners, or support brackets.

The spacing between the PCB 405 and the PCB 420 can include one or more values or ranges. For example, the spacing can be 3 millimeters. As another example, the spacing can be 5 millimeters. As another example, the spacing can be 10 millimeters. As another example, the spacing can be within a range of 3 millimeters to 20 millimeters. The spacing can be selected based on factors such as NFC coil inductance, quality factor, or sensitivity of the NFC antenna. The housing 305 can include one or more non-conductive structural members, such as molded support ribs, polymer standoffs, or dielectric spacers, to maintain or otherwise establish a fixed mechanical spacing between PCB 405 and PCB 420. The non-conductive structural members can prevent either of (or both) the PCB 405 or the PCB 420 from shifting towards one another during operation or assembly.

The spacing between the PCB 405 and the PCB 420 can provide for a reduction in signal interference. For example, the spacing can reduce an amount of magnetic loading (that is experienced by the NFC antenna) that can result from nearby conductive structures (of the PCB 420). The reduction in the amount of magnetic loading can maintain one or more of stable tuning, consistent field strength, and reliable NFC communication of the NFC antenna. As another example, the spacing can reduce a coupling of broadband electrical noise (from the LTE antenna) experienced at the NFC circuitry. The electrical noise can come from one or more sources, such as LTE power-amplifier stages, envelope-tracking modules, radio frequency transceiver components, or switching power supplies of the PCB 420.

The reduction in cross-talk interference (between the NFC antenna and the LTE antenna) can be supplemented with electrical isolation techniques, such as the inclusion of local shielding materials, segmented or discontinuous ground regions, return-path management layouts, or designated electrical keep-out zones near the NFC antenna. For example, the PCB 405 can include shielding material to create a physical barrier between the NFC antenna and one or more conductive structures of the PCB 420. The utilization of one or more of the spacing (between the PCB 405 and the PCB 420) and the electrical isolation techniques can reduce potential coupling pathways between the NFC antenna and the LTE antenna which can improve coexistence of multiple radios within the housing 305.

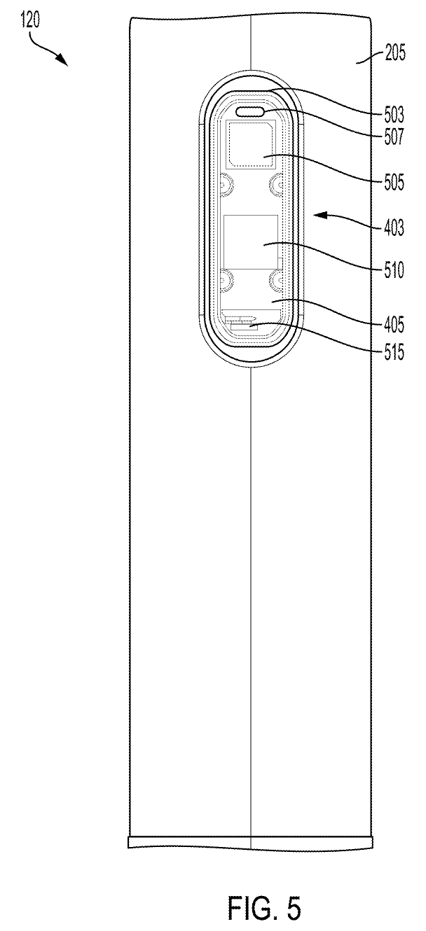

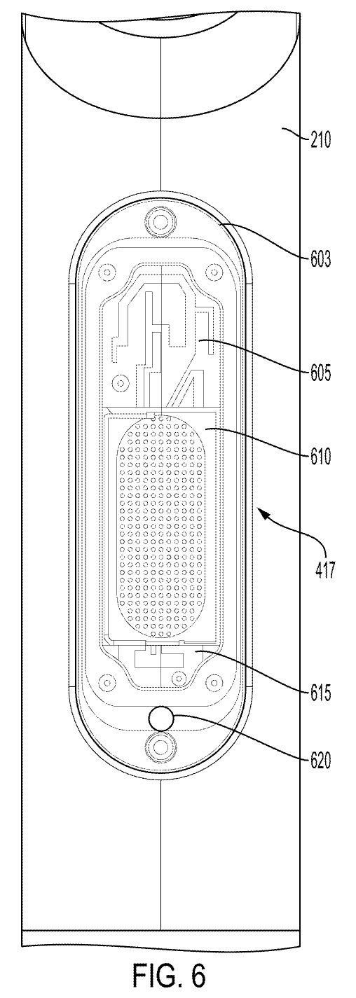

The connectivity assemblies can be positioned or otherwise placed within the frame 120 such that at least one portion of the connectivity assemblies are positioned proximate to an aperture on the frame. For example, as shown in FIG. 5, the connectivity assembly 403 is positioned proximate to a region 503 of the frame 120. As another example, as shown in FIG. 6, the connectivity assembly 417 is positioned proximate to a region 603 of the frame 120. The region 503 can be positioned or otherwise located on the side 205 of the frame 120. The region 503 can provide an opening or a void for one or more communication devices of the connectivity assembly 403. For example, the region 503 can provide an opening for one or more of antennas, transmitters, transceivers, or receivers. The region 603 can be positioned or otherwise located on the side 210 of the frame. The region 603 can provide an opening or a void for one or more communication devices of the connectivity assembly 417.

The PCB 405 can house or otherwise support one or more communication devices. For example, as shown in FIG. 5, the connectivity assembly 403 includes a first communication device 505, a second communication device 510, and a third communication device 515. The PCB 405 is further shown to house the communication device 505, the communication device 510, and the communication device 515. The PCB 405 can house one or more communication devices by providing an area or a surface to receive the communication devices. As shown in FIG. 5, the PCB 405 can include a port 507. The port 507 can refer to or include a plug or receptacle for an electronic cord or device. For example, the port 507 can be a universal serial bus (USB) type c port. As another example, the port 507 can include a USB type a port. As another example, the port 507 can be direct current power port. The port 507 can electrically couple one or more devices (e.g., devices plugged into the port 507) with the battery pack 105 such that energy can be discharged from the battery pack 105. Additionally, the port 507 can facilitate the exchange of data or information between the controller 215 and the device plugged into the port 507.

The communication devices of the connectivity assembly 403 can conform to or adhere to one or more communication protocols. The connectivity assembly 403 can include communication devices that conform to one or more of Global Navigation Satellite System (GNSS), Ultra-Wide Band (UWB), or Near-Field Communication (NFC). As an example, the communication device 505 can include a GNSS antenna. As another example, the communication device 510 can include an NFC antenna. As another example, the communication device 515 can include an UWB antenna. The communication protocols can be wireless communication protocols which are optimized or otherwise designed for short-range communication.

The connectivity assembly 417 can include one or more communication devices. For example, as shown in FIG. 6, the connectivity assembly 417 includes a first communication device 605 and a second communication device 615. The communication devices of the connectivity assembly 417 can conform to one or more communication protocols. The connectivity assembly 417 can include communication devices that conform to one or more of Long Term Evolution (LTE), Bluetooth, or Wi-Fi. For example, the communication device 605 can include an LTE antenna. As another example, the communication device 615 can include a Wi-Fi antenna. The communication protocols can be wireless communication protocols which are optimized or otherwise designed for long-range communication.

The assembly 200 can include at least one audio device. For example, as shown in FIG. 6, the connectivity assembly 417 includes a speaker 610. The speaker 610 can positioned within the frame 120 such that at least portion of the speaker 610 is external to the frame 120. For example, the speaker 610 can be positioned within the region 603 such that at least a portion of the speaker 610 is external (outside of) to the frame 120. The speaker 610 can produce sound or other possible audio. For example, the speaker 610 can produce a sound, which is discernable to a person located proximate to the bike 100. As shown in FIG. 6, the connectivity assembly 417 includes button 620. The button 620 can be pressed or actuated to trigger a reset, a reload, or a restart of operation for any one of the devices described herein.

The connectivity assemblies can collect, obtain, or otherwise receive one or more sets of information. For example, the connectivity assemblies can receive information that was obtained by one or more communication devices. The connectivity assemblies can receive information from one or more devices. For example, the connectivity assembly 403 can receive one or more signals from a mobile device. As another example, the connectivity assembly 417 can receive one or more signals from a Bluetooth device.

The controller 215 can receive or otherwise obtain one or more signals (e.g., inputs, pings, electrical voltage, etc.) from the connectivity assemblies. The signals can cause the controller 215 to perform one or more actions. For example, the controller 215 can, responsive to receipt of one or more inputs from the connectivity assemblies, cause the bike 100 to perform one or more actions. As another example, the controller 215 can provide one or more responses, via the connectivity assemblies, to a computing device.

The actions, performed by the bike 100 or one or more components thereof, can include at least one of a production of light by one or more light sources of the bike 100, an over-the-air (OTA) update to adjust one or more aspects of the bike 100, a production of sound by one or more audio devices, an adjustment to an amount of energy discharged by one or more energy storage devices of the bike 100, or a transmission (to a computing device) of one or more signals to provide location information of the electric bicycle.

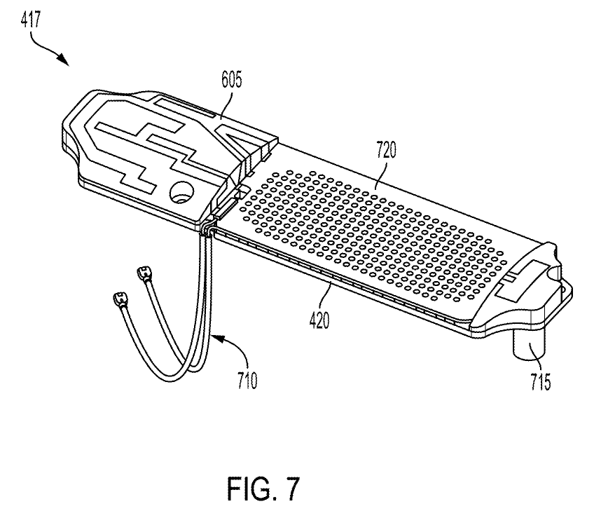

FIG. 7 depicts the connectivity assembly 417, in accordance with some aspects. The PCB 420 can provide a surface or an area to house one or more components of the connectivity assembly 417. For example, the PCB 420 can provide an area for the communication device 605. As another example, the PCB 420 can provide an area for one or more mounting holes 715. The mounting holes 715 can receive one or more fasteners to couple the connectivity assembly 417 with one or more components of the assembly 200. The connectivity assembly 417 can include a ground plane 720 and one or more cables 710. The ground plane 720 can include one or more types of ground planes. For example, the ground plane 720 is shown as a perforated ground plane in FIG. 7. The cables 710 can electrically couple or communicably couple the connectivity assembly 417 with one or more components. For example, the cables 710 can communicably couple the connectivity assembly 417 with the battery pack 425.

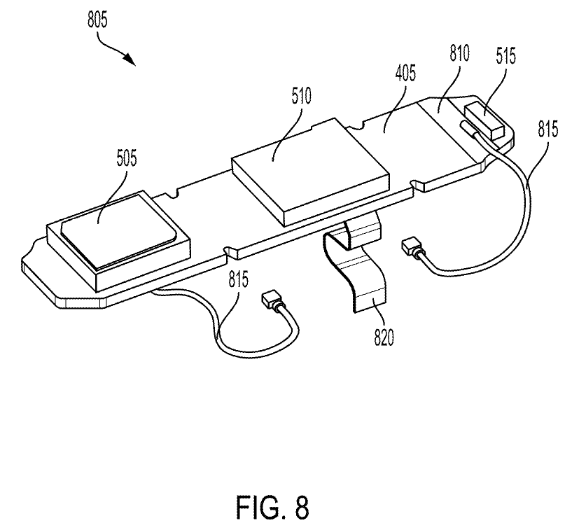

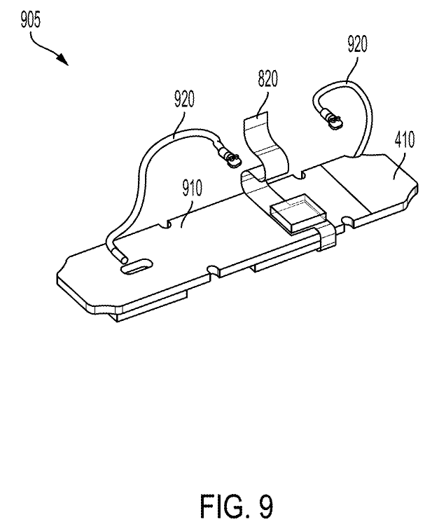

FIGS. 8-9 depict example sub-assemblies for the connectivity assembly 403, in accordance with some aspects. The connectivity assembly 403 can include a sub-assembly 805 (as shown in FIG. 8) and a sub-assembly 905 (as shown in FIG. 9). The sub-assembly 805 can include the PCB 405. The sub-assembly 905 can include the PCB 410. The sub-assembly 805 can be communicably coupled with the sub-assembly 905 via connector 820. The connector 820 can include one or more of PCB ribbon cabling, board to board connectors, or other possible electrical coupling cabling.

The sub-assembly 805 can include at least one ground plane 810. The ground plane 810 can provide or route current to ground. For example, the ground plane 810 can ground the PCB 405. The sub-assembly 805 can include at least one cable 815. The cables 815 can include co-axial cabling to couple the sub-assembly 805 with one or more components.

The PCB 410 can provide a surface or an area to house one or more components of the sub-assembly 905. For example, the PCB 410 can house a ground plane 910. As another example, the PCB 410 can include one or more terminals or ports for which cabling 920 can couple with the sub-assembly 905. The cabling 902 can refer to or include cabling similar to that of the cabling 815.

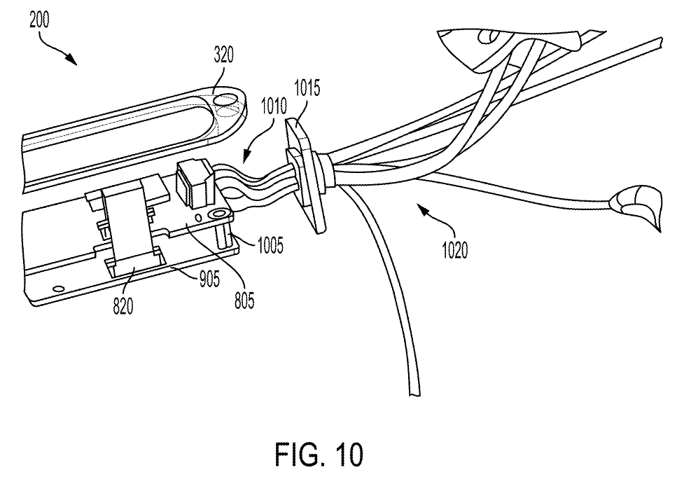

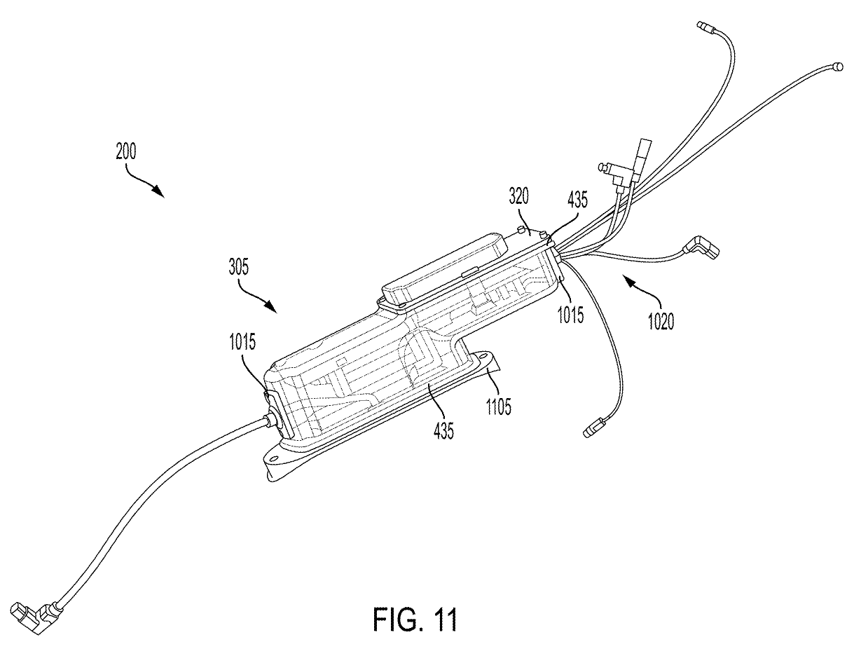

FIGS. 10-11 depict the assembly 200, in accordance with some aspects. As shown in FIG. 10, the sub-assembly 805 is electrically coupled and communicably coupled with sub-assembly 905 via the connector 820. The connector 820 can facilitate the transfer of data or information between the sub-assembly 805 and the sub-assembly 905. The sub-assembly 805 can include a cable assembly 1010. The cable assembly 1010 can include one or more of connectors, terminals, or pin headers to receive one or more cables. The cable assembly 1010 can electrically couple the sub-assembly 805 to one or more cables or components of the assembly 200 or the bike 100.

The assembly 200 can include at least one fitting 1015. The fitting 1015 (e.g., a cable gland, a cable connector, a barrier, a cable fitting, etc.) can isolate or enclose one or more exposed cables (within the housing 305) from an environment outside of the housing 305. The cables of the cable assembly 1010 can pass-through or otherwise transition, via the fitting 1015, to form or establish cable assembly 1020. The cable assembly 1020 can refer to or include one or more portions or segments of the cable assembly 1010 that are external to the fittings 1015. Stated otherwise, the cable assembly 1020 can be a sub-portion (of the cable assembly 1010) that is external to or otherwise not housed within the housing 305.

As shown in FIG. 11, the housing 305 can include a first fitting 1015 and a second fitting 1015. The fittings 1015 can provide one or more narrow openings such that cables can be (1) secured to the housing 305 and (2) allowed to escape the housing 305. The assembly 200 can include one or more members or structures to couple with the connectivity assembly 403, the connectivity assembly 417, the housing 305, or the frame 120. For example, FIG. 11 shows the member 320 coupled with the first aperture 435. As another example, FIG. 11 shows a member 1105, of the assembly 200, coupled with the second aperture 435. The members (e.g., the member 320, the member 1105, etc.) can isolate, insulate, barricade, or otherwise protect one or more internal components (within the housing 305) from the environment.

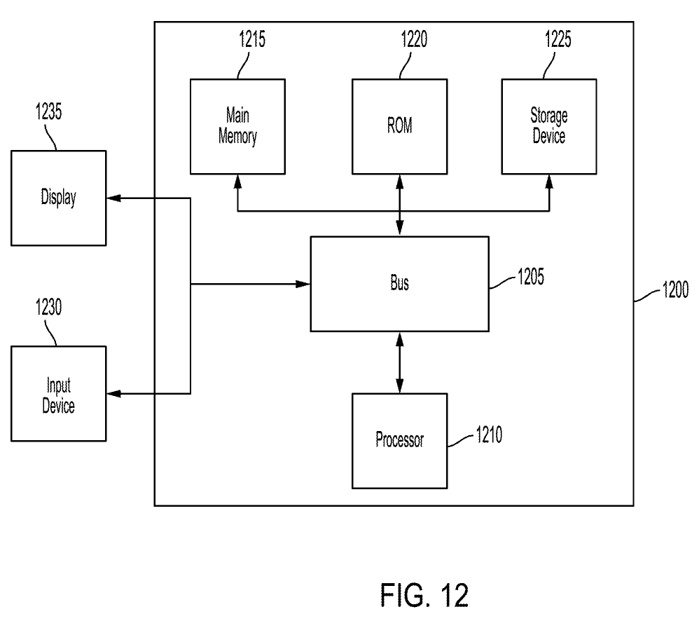

FIG. 12 is a block diagram illustrating an architecture for a computing system 1200 that can be employed to implement elements of the systems, methods, and assemblies described and illustrated herein. For example, the controller 215 can be or include the computing system 1200. The computing system 1200 can include at least one bus 1205 or other communication component for communicating information and at least one processor 1210 or processing circuit coupled to the bus 1205 for processing information. The computing system 1200 can also include one or more processors 1210 or processing circuits coupled to the bus for processing information. The computing system 1200 also includes at least one main memory 1215, such as a random access memory (RAM) or other dynamic storage device, coupled to the bus 1205 for storing information, and instructions to be executed by the processor 1210. The main memory 1215 can be used for storing information during execution of instructions by the processor 1210. The computing system 1200 may further include at least one read only memory (ROM) 1220 or other static storage device coupled to the bus 1205 for storing static information and instructions for the processor 1210. A storage device 1225, such as a solid state device, magnetic disk or optical disk, can be coupled to the bus 1205 to persistently store information and instructions.

The computing system 1200 may be coupled via the bus 1205 to a display 1235, such as a liquid crystal display, or active matrix display, for displaying information to a user such as a rider of the bike 100 or other end user. An input device 1230, such as a keyboard or voice interface may be coupled to the bus 1205 for communicating information and commands to the processor 1210. The input device 1230 can include a touch screen display 1235. The input device 1230 can also include a cursor control, such as a mouse, a trackball, or cursor direction keys, for communicating direction information and command selections to the processor 1210 and for controlling cursor movement on the display 1235.

The processes, systems and methods described herein can be implemented by the computing system 1200 in response to the processor 1210 executing an arrangement of instructions contained in main memory 1215. Such instructions can be read into main memory 1215 from another computer-readable medium, such as the storage device 1225. Execution of the arrangement of instructions contained in main memory 1215 causes the computing system 1200 to perform the illustrative processes described herein. One or more processors in a multi-processing arrangement may also be employed to execute the instructions contained in main memory 1215. Hard-wired circuitry can be used in place of or in combination with software instructions together with the systems and methods described herein. Systems and methods described herein are not limited to any specific combination of hardware circuitry and software.

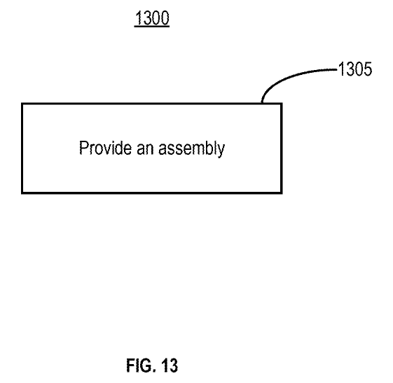

FIG. 13 is a block diagram of a process 1300, according to some aspects. The process 1300 can be performed or implemented during an assembly process or manufacture process of the bike 100 or one or more components thereof. For example, the process 1300 can be performed when the frame 120 is adhered to or otherwise attached to one or more additional components of the bike 100.

At act 1305, an assembly can be provided. For example, the assembly 200 can be provided. As another example, one or more components, sub-assemblies, or elements of the assembly 200 can be provided. The assembly 200 can be provided during the manufacture of the bike 100. The assembly 200 can be retrofitted or otherwise added to the bike 100 subsequent to assembly of the bike 100. The providing of the assembly 200 can include the providing or otherwise making available the components, elements, or sub-assemblies of the assembly 200. For example, one or more connectivity assemblies (of the assembly 200) can be providing during act 1305.

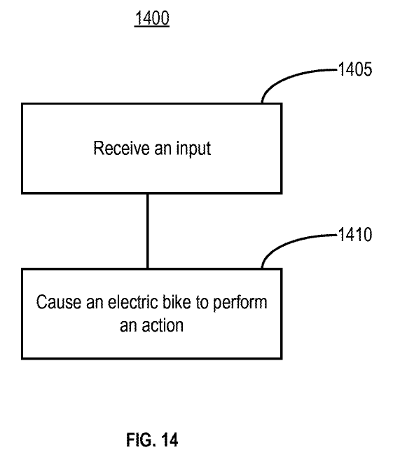

FIG. 14 depicts a block diagram of method 1400, according to some aspects. The method 1400 or one or more acts or steps of the method 1400 can be combined, separated, omitted, skipped, repeated, or otherwise altered. For example, a single act can be separated into two or more acts. As another example, a first act can be combined with a second act of the method 1400.

At act 1405, an input can be received. For example, at least one processor can receive an input from at least one connectivity assembly of the assembly 200. As another example, the controller 215 can receive an input from the connectivity assembly 403 or the connectivity assembly 417. The input can correspond to one or more communication protocols. For example, the input can be received (by the controller 215) responsive to an interaction between the connectivity assembly 403 and a computing device via NFC communication (e.g., a communication protocol).

At act 1410, an action can be performed. For example, the controller 215 can transmit one or more control signals to cause the drive unit 155 to actuate to either active or deactivate the drive unit 155. As another example, the controller 215 can transmit one or more signals to the light 125 to cause the light 125 to produce light.

The micromobility device referred to herein as bike 100 can be or include at least one drive unit (e.g., a propulsion system), at least one wheel, at least one battery pack, and a frame. The drive unit, the wheel, and the battery pack can be coupled with the frame. The drive unit can rotate the wheel to propel the micromobility device. The micromobility device can include the battery pack to power the drive unit and rotate the wheel with or without application of a mechanical force to a pedal assembly by the user. For example, the micromobility device can the propelled by a mechanical force provided by the user to the pedal assembly, by an electrical force provided by a battery pack to a motor, or some combination thereof. The micromobility device can include single rider bicycles, tandem bicycles, cargo bicycles, motor-assist bicycles, pedicabs, electric-assist bicycles, road bicycles, mountain bicycles, electric scooters, electric skateboards, standing devices, or unicycles, or devices with one, two, three, four or more than four wheels.

In various embodiments, a micromobility device (which may be or include the bike 100) may be designed to support a gross vehicle weight, defined as the combined mass of the device, rider, payload, and accessories, which corresponds to applicable regulatory or industry standards for micromobility devices. By way of example and without limitation, certain bicycle-based and electric bicycle standards, such as ISO 4210 and EN 15194, contemplate testing and design assumptions for a total mass on the order of approximately 120 kilograms, inclusive of rider and load, while other micromobility categories, including scooters, mopeds, and cargo-oriented devices, may be designed for higher gross vehicle weights, such as greater than 120 kilograms, greater than 150 kilograms, or greater than 200 kilograms, depending on jurisdiction, classification, and intended use. In some embodiments, the micromobility device may be configured to comply with regulations and testing protocols, such as those administered by the U.S. Consumer Product Safety Commission, which may specify structural strength, braking performance, and fatigue testing criteria corresponding to representative rider and payload masses. References to such weight values are intended to reflect regulatory examples rather than to impose fixed design limits on the disclosed embodiments.

The propulsion system may include an electric motor, a human-powered drivetrain, or a combination thereof, and may be configured in hub-based, mid-mounted, or remote arrangements using chain, belt, shaft, gear, friction, or direct-drive mechanisms to transmit torque to at least one ground-engaging element. An energy storage system may be provided to store electrical energy for powering the propulsion system and auxiliary components, and may include one or more batteries, capacitors, fuel cells, or other energy storage technologies that may be removable, fixed, swappable, or distributed across multiple locations on the device. The energy storage system may further include charging circuitry, battery management systems, thermal management components, and monitoring elements configured to meet or exceed applicable electrical standards for micromobility devices, including but not limited to UL 2849, UL 2272, IEC 62133, or equivalent regional or international standards.

The micromobility device may further include a control system comprising one or more processors, controllers, sensors, and communication interfaces configured to manage propulsion output, braking behavior, energy usage, and auxiliary functions. The control system may regulate motor output based on rider input, operating conditions, load, speed, inclination, or environmental sensing, and may support software-based features such as diagnostics, data logging, fleet management integration, geofencing, or over-the-air software updates. Braking systems may include mechanical, hydraulic, electromagnetic, regenerative, or combined braking mechanisms, and the device may further include stability or features such as traction control, anti-lock braking, suspension systems, steering dampening elements, lighting systems, and audible warning devices. In various embodiments, the micromobility device may be designed to comply with applicable operational and mechanical standards, including but not limited to ISO 4210, EN 15194, SAE J3194, applicable portions of 16 CFR Part 1512, and corresponding regional, national, or municipal micromobility regulations governing speed, power output, braking performance, lighting, and gross vehicle weight classifications.

The micromobility device may include a rider interface configured to receive user input through handlebars, grips, pedals, throttles, buttons, touch interfaces, or gesture-based controls, and may alternatively or additionally include a payload interface configured to support cargo, delivery containers, child seats, or autonomous payload modules. In some embodiments, the micromobility device may be configured as, or convertible between, multiple micromobility form factors, including electric bicycles, scooters, mopeds, seated or standing ride-on devices, or cargo and utility vehicles, wherein such configurations may share common components or differ only in selected structural, propulsion, control, or interface elements. Unless otherwise stated, the components and features described herein may be combined, omitted, rearranged, scaled, or substituted without departing from the scope of the disclosure, and references to regulatory standards or weight limits are intended to be exemplary and non-limiting.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer-based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C#, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device,” “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, and although many of the examples presented herein involve specific combinations of method acts or system elements, those acts and those elements may be combined in other ways to accomplish the same objectives. Acts, elements, and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations, elements, or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms, as used herein, are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A,’ only ‘B,’ as well as both ‘A’ and ‘B.’ Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

Further relative parallel, perpendicular, vertical, or other positioning or orientation descriptions include variations within +/-10% or +/-10 degrees of pure vertical, parallel or perpendicular positioning. References to “approximately,” “substantially” or other terms of degree include variations of +/-10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. An assembly of an electric bicycle, comprising:
a housing configured to receive a first connectivity assembly and a second connectivity assembly;
the housing configured to be disposed at least partially within a frame of the electric bicycle;
the first connectivity assembly including a first printed circuit board including a first antenna associated with a first wireless communication protocol;
the second connectivity assembly including a second printed circuit board including a second antenna associated with a second wireless communication protocol; and
at least one processor, coupled with memory, the first connectivity assembly, and the second connectivity assembly, the at least one processor configured to:
receive, from at least one of the first antenna or the second antenna, an input; and
cause the electric bicycle to perform an action based on the input.

2. The assembly of claim 1, comprising:
the frame including a down tube having a first side and a second side opposite to the first side; and
the housing configured to be disposed within a cavity of the down tube such that (i) the first connectivity assembly is disposed at the first side and (ii) the second connectivity assembly is disposed at the second side.

3. The assembly of claim 1, comprising:
the first wireless communication protocol optimized for short-range communication, and the first wireless communication protocol including at least one of:
Global Navigation Satellite System (GNSS);
Ultra-Wide Band (UWB); or
Near-Field Communication (NFC); and
the second wireless communication protocol including at least one of:
Long Term Evolution (LTE);
Bluetooth; or
Wi-Fi.

4. The assembly of claim 1, comprising:
the second printed circuit board including an audio device;
the audio device configured to be disposed within the frame such that at least a portion of the audio device is positioned external to the frame; and
the audio device configured to produce sound.

5. The assembly of claim 1, comprising:
the housing including:
a first region to provide a first area for at least a portion of the first antenna; and
a second region to provide a second area for at least a portion of the second antenna;
a first interlocking member configured to:
couple with the first region via one or more first fasteners; and
provide, responsive to coupling with the first region, a first barrier for the first antenna; and
a second interlocking member configured to:
couple with the second region via one or more second fasteners; and
provide, responsive to coupling with the second region, a second barrier for the second antenna.

6. The assembly of claim 1, wherein the action includes at least one of:
a production of light by one or more light sources of the electric bicycle;
an over-the-air (OTA) update to adjust one or more aspects of the electric bicycle;
a production of sound by one or more audio devices of the electric bicycle;
an adjustment to an amount of energy discharged by one or more energy storage devices of the electric bicycle; or
a transmission, to a computing device, of one or more signals to provide location information of the electric bicycle.

7. The assembly of claim 1, comprising:
the at least one processor configured to:
receive the input from the first antenna; and
actuate, responsive to receipt of the input, a drive unit of the electric bicycle.

8. The assembly of claim 1, comprising:
the first printed circuit board and the second printed circuit board selectively placed, within the housing, to establish a spacing between the first printed circuit board and the second printed circuit board to reduce cross-talk interference between the first antenna and the second antenna.

9. The assembly of claim 1, comprising:
the first printed circuit board including:
a third antenna associated with a third wireless communication protocol; and
a fourth antenna associated with a fourth wireless communication protocol; and
the first wireless communication protocol including Near-Field Communication (NFC), the third wireless communication protocol including Global Navigation Satellite System (GNSS), and the fourth wireless communication protocol including Ultra-Wide Band (UWB).

10. An electric bicycle, comprising:
a frame; and
an assembly, including:
a housing configured to receive a first connectivity assembly and a second connectivity assembly;
the housing configured to be disposed at least partially within the frame;
the first connectivity assembly including a first printed circuit board configured to house a first communication device associated with a first communication protocol;
the second connectivity assembly including a second printed circuit board configured to house a second communication device associated with a second communication protocol; and
at least one processor, coupled with memory, configured to:
receive, from at least one of the first communication device or the second communication device, an input; and
cause the electric bicycle to perform an action based on the input.

11. The electric bicycle of claim 10, wherein the frame includes a down tube having a first side and a second side opposite to the first side, comprising:
the housing configured to be disposed within the frame such that (i) the first connectivity assembly is disposed at the first side and (ii) the second connectivity assembly is disposed at the second side.

12. The electric bicycle of claim 10, wherein the first communication protocol includes at least one of Global Navigation Satellite System (GNSS), Ultra-Wide Band (UWB), or Near-Field Communication (NFC), and wherein the second communication protocol includes at least one of Long Term Evolution (LTE), Bluetooth, or Wi-Fi.

13. The electric bicycle of claim 10, comprising:
the second printed circuit board including an audio device;
the audio device configured to be disposed within the frame such that at least a portion of the audio device is positioned external to the frame; and
the audio device configured to produce sound.

14. The electric bicycle of claim 10, comprising:
the housing including:
a first region to provide a first area for at least a portion of the first communication device; and
a second region to provide a second area for at least a portion of the second communication device;
a first interlocking member configured to:
couple with the first region via one or more first fasteners; and
provide, responsive to coupling with the first region, a first barrier for the first communication device; and
a second interlocking member configured to:
couple with the second region via one or more second fasteners; and
provide, responsive to coupling with the second region, a second barrier for the second communication device.

15. The electric bicycle of claim 10, wherein the action includes at least one of:
a production of light by one or more light sources of the electric bicycle;
an over-the-air (OTA) update to adjust one or more aspects of the electric bicycle;
a production of sound by one or more audio devices of the electric bicycle;
an adjustment to an amount of energy discharged by one or more energy storage devices of the electric bicycle; or
a transmission, to a computing device, of one or more signals to provide location information of the electric bicycle.

16. The electric bicycle of claim 10, comprising:
the at least one processor configured to:
receive the input from the first communication device; and
actuate, responsive to receipt of the input, a drive unit of the electric bicycle.

17. The electric bicycle of claim 10, comprising:
a saddle; and
the housing configured to be disposed within the frame such that the first communication device is within a field of view from the saddle of the electric bicycle.

18. A method, comprising:
providing an assembly;
the assembly including a housing:
the housing configured to receive a first connectivity assembly and a second connectivity assembly;
the housing configured to be disposed at least partially within a frame of an electric bicycle;
the first connectivity assembly to house a first communication device associated with a first communication protocol;
the second connectivity assembly to house a second communication device associated with a second communication protocol;
the assembly including at least one processor coupled with memory; and
the at least one processor configured to:
receive, from at least one of the first communication device or the second communication device, an input; and
cause the electric bicycle to perform an action based on the input.

19. The method of claim 18, wherein the frame includes a down tube having a first side and a second side opposite to the first side, and wherein the housing is configured to be disposed within the frame such that (i) the first connectivity assembly is disposed at the first side and (ii) the second connectivity assembly is disposed at the second side.

20. The method of claim 18, wherein:
the at least one processor configured to:
receive the input from the first communication device; and
actuate, responsive to receipt of the input, a drive unit of the electric bicycle.
